(19) United States
(12) Patent Application Publication
(10) Pub. No.: US 2015/0282316 A1
(43) Pub. Date: Oct. 1, 2015

(54) PRINTED CIRCUIT BOARD

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: ZHANG-LONG PENG, Wuhan (CN); CHUN-SHENG CHEN, New Taipei (TW)

(21) Appl. No.: 14/543,303

(22) Filed: Nov. 17, 2014

(30) Foreign Application Priority Data
Mar. 26, 2014 (CN) 201410115607.4

(51) Int. Cl. H05K 1/11; H05K 1/18; H05K 1/09

(52) U.S. Cl. CPC H05K 1/111; H05K 1/09; H05K 1/181; H05K 2201/10992; H05K 2201/10242

(57) ABSTRACT

A printed circuit board which avoids the melding of closely adjacent solders includes a top surface, a number of electronic elements and a number of solders. The top surface includes a plurality of copper clad areas. Each copper clad area includes a head area and a neck area. The neck area is positioned on same side of the head area. The neck area includes two edges extended from a fringe of the head area and a terminal point. The two edges intersect at the terminal point. The electronic elements are positioned at the head area. Each solder includes a soldering portion and a tip portion. The soldering portion is attached on the head area and surrounds the electronic element. The tip portion is attached on the neck area. A fringe of the solder is same as the fringe of the copper clad area.

### CROSS-REFERENCE TO RELATED APPLICATIONS

This application claims priority to Chinese Patent Application No. 201410115607.4 filed on Mar. 26. 2014, the contents of which are incorporated by reference herein.

### FIELD

The present disclosure relates to printed circuit boards.

### BACKGROUND

Electronic elements are usually fixed to copper clad areas on printed circuit boards by solder. The shape of the copper clad area is generally round. When two copper clad areas are closely adjacent, the solders attached on the copper clad areas may meld together.

### BRIEF DESCRIPTION OF THE DRAWINGS

Implementations of the present technology will now be described, by way of example only, with reference to the attached figures.

FIG. 1 is a diagrammatic view of a top surface of a printed circuit board with solder omitted.

FIG. 2 is similar to FIG. 1, but with solder on the top surface.

FIG. 3 is a cross sectional view of a printed circuit board taken along line III-III of FIG. 2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series, and the like.

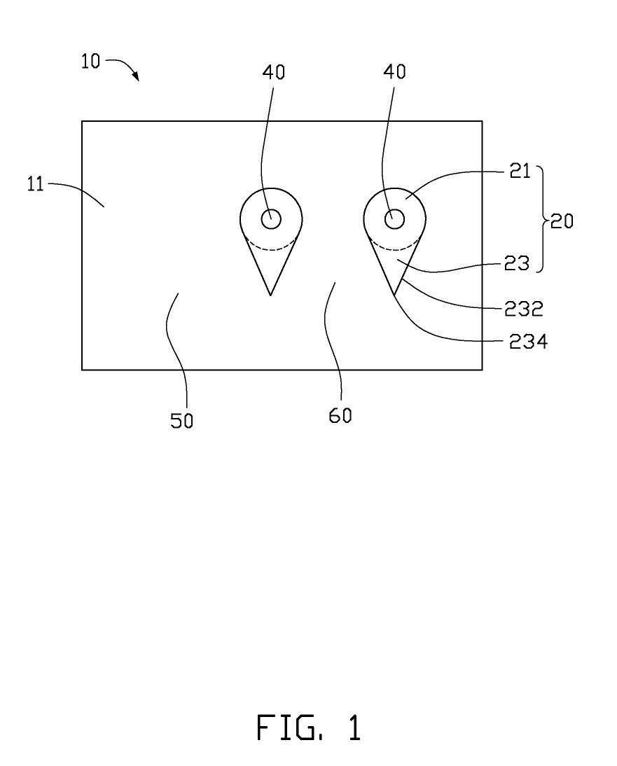

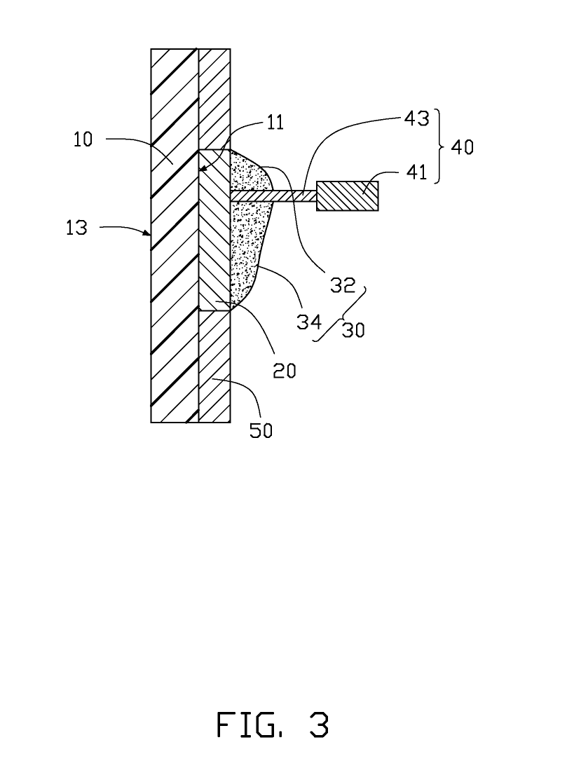

FIGS. 1 illustrates a printed circuit board 10 which can include a top surface 11 and a bottom surface 13 (shown in FIG. 3). The top surface 11 includes a number of copper clad areas 20 and a solder mask area 50 surrounding the copper clad areas 20. In at least one embodiment, the solder mask area 50 is desiccated green oil. The top surface 11 includes two copper clad areas 20.

The copper clad area 20 includes a head area 21 and a neck area 23 extending from the head area 21. An area of the head area 21 is greater than that of the neck area 23. The head area 21 is substantially round. Two neck areas 23 are positioned on the same side of the head areas 21. The neck area 23 includes two edges 232 extended from the fringe of the head area 21 and a terminal point 234. The two edges 232 intersect at the terminal point 234. The two edges 232 have substantially the same length. An angle between the two edges 232 is an acute angle.

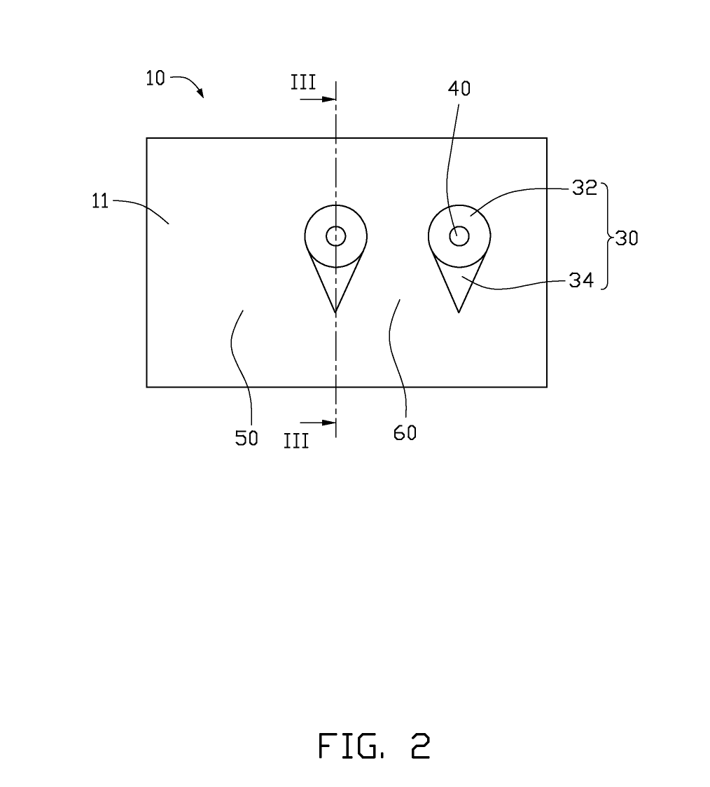

Referring to FIGS. 2 and 3, an electronic element 40 includes a main body 41 and a pin 43 extended from the main body 41. The pin 43 is affixed on the head area 21 by solder 30. The solder 30 covers the copper clad area 20. The solder 30 includes a soldering portion 32 and a tip portion 34. The soldering portion 32 is attached on the head area 21 and surrounds the pin 43. The tip portion 34 is attached on the neck area 23. Because the solder mask area 30 surrounds the copper clad area 20, the solder mask area 30 prevents the attachment of the solder 30 on other area of the circuit board 10 beyond the copper clad area 20. Thus, the solder 30 can only attach on the copper clad area 20. A rim of the solder 30 is same as that of the copper clad area 20. A height of the soldering portion 32 is greater than that of the tip portion 34. The soldering portion 32 has a high point (not labeled). The high point (in relation to the circuit board) of soldering portion 32 is generally positioned symmetrically about the attached portion of the electronic element (e.g. pin 43).

Also referring to FIG. 1, a gap 60 is formed between two copper clad areas 20. Because the rim of the solder 30 is same as that of the copper clad area 20, each of two solders 30 have the gap 60 between them. Because the copper clad area 20 includes the neck portion 23, the two adjacent neck portions 23 are spaced away. Thus, the gap 60 between the two copper clad areas 20 and the two solders 30 is present. Therefore, any melding of the two solders 30 can be avoided.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A printed circuit board comprising:
a top surface comprising a plurality of copper clad areas, each copper clad area comprises a head area and a neck area, the neck areas positioned on a same side of the head area, the neck area comprising two edges extended from a fringe of the head area and a terminal point, the two edges intersected at the terminal point;
a plurality of electronic elements positioned at the head areas; and
a plurality of solders, each solder comprises a soldering portion and a tip portion, the soldering portion is attached on the head area and surrounding the electronic element, the tip portion is attached on the neck area, a fringe of the solder is on the same as the fringe of the copper clad area.

2. The printed circuit board as claimed in claim 1, wherein the two edges have same length.

3. The printed circuit board as claimed in claim 1, wherein an angle between the two edges is an acute angle.

4. The printed circuit board as claimed in claim 1, wherein the top surface further comprising a solder mask area surrounding the copper clad areas.

5. The printed circuit board as claimed in claim 4, wherein the solder mask area is desiccated green oil.

6. A printed circuit board comprising:
a substrate having:
a first surface having at least a first edge; and
a plurality of copper clad areas positioned on the first surface of the substrate, each copper clad area having a head area and a neck area;
wherein, each neck area has a first neck edge and a second neck edge extending from an edge of the head area to a terminal point, with the second neck are edge substantially opposite the first neck edge; and
wherein, the all of plurality of terminal points are positioned between the plurality of head areas and a same portion of the at least first edge of the first; and
a plurality of electronic elements connected to the substrate;
wherein, each of the plurality of electronic elements is connected to the head area of one of the plurality of copper clad areas by solder; and
wherein, the solder connecting the electronic elements to the copper clad area covers only the copper clad area, with a soldering portion of the solder substantially covering the head area and a tip portion of the solder substantially covering the neck area

7. The printed circuit board as claimed in claim 6, wherein the first neck edge and the second neck edge have same length.

8. The printed circuit board as claimed in claim 6, wherein an angle between the first neck edge and the second neck edge is an acute angle.

9. The printed circuit board as claimed in claim 6, wherein the first surface further comprises a solder mask area surrounding the copper clad areas.

10. The printed circuit board as claimed in claim 6, wherein an area of the head area is greater than that of the neck area.

11. A printed circuit board comprising:
a substrate having:
a first surface having a bottom edge, a top edge opposite, and substantially parallel, to the bottom edge, and a first side edge and a second side edge connecting the bottom edge to the top edge and substantially perpendicular to the bottom edge and the top edge, with the first side edge substantially parallel to the second side edge; and
a plurality of copper clad areas positioned on the first surface of the substrate, each copper clad area having a head area and a neck area;
wherein, each neck area has a first neck edge and a second neck edge extending from an edge of the head area to a terminal point, with the second neck are edge substantially opposite the first neck edge; and
wherein, the all of plurality of terminal points are positioned between the plurality of head areas and a same first surface edge; and
a plurality of electronic elements connected to the substrate;
wherein, each of the plurality of electronic elements is connected to the head area of one of the plurality of copper clad areas by solder; and
wherein, the solder connecting the electronic elements to the copper clad area covers only the copper clad area, with a soldering portion of the solder substantially covering the head area and a tip portion of the solder substantially covering the neck area.

12. The printed circuit board as claimed in claim 11, wherein the first neck edge and the second neck edge have same length.

13. The printed circuit board as claimed in claim 11, wherein an angle between the first neck edge and the second neck edge is an acute angle.

14. The printed circuit board as claimed in claim 11, wherein the first surface further comprises a solder mask area surrounding the copper clad areas.

15. The printed circuit board as claimed in claim 14, wherein the solder mask area is desiccated green oil.

16. The printed circuit board as claimed in claim 11, wherein an area of the head area is greater than that of the neck area.

17. The printed circuit board as claimed in claim 11, wherein the head area is round.

18. The printed circuit board as claimed in claim 11, wherein the electronic element comprises a main body and a pin extended from the main body, the pin is welded on the head area by the soldering portion.

19. The printed circuit board as claimed in claim 18, wherein the soldering portion is symmetric in relation to the pin.

20. The printed circuit board as claimed in claim 18, wherein the soldering portion has a high point, the high point is attached on the pin.
